(19) United States
(12) Patent Application Publication
(10) Pub. No.: US 2016/0372695 A1
(43) Pub. Date: Dec. 22, 2016

(54) LAMINATED ORGANIC ELECTROLUMINESCENT DEVICE AND METHOD OF MANUFACTURING THE SAME, AND DISPLAY DEVICE

(71) Applicant: BOE TECHNOLOGY GROUP CO., LTD., Beijing (CN)

(72) Inventors: Wentao Bi, Beijing (CN); Zhiqiang Jiao, Beijing (CN)

(21) Appl. No.: 14/776,556

(22) PCT Filed: Feb. 15, 2015
(86) PCT No.: PCT/CN2015/073104

§ 371 Date: Sep. 14, 2015

(30) Foreign Application Priority Data
Nov. 25, 2014 (CN) 201410690834.X

(51) Int. Cl. H01L 51/50; H01L 51/56; H01L 51/00; H01L 27/32

(52) U.S. Cl. CPC H01L 51/5008; H01L 27/3209; H01L 51/56; H01L 51/001; H01L 2251/301; H01L 2251/303; H01L 2251/558; H01L 51/0046; H01L 51/0055; H01L 51/0078; H01L 51/005; H01L 51/006; H01L 51/0058; H01L 51/0072

(57) ABSTRACT

The present disclosure provides a laminated organic electroluminescent device and a method of manufacturing the same, and a display device comprising the laminated organic electroluminescent device, for reducing number of layers of and improving luminescence efficiency of the laminated organic electroluminescent device. The laminated organic electroluminescent device comprises at least two stacked light emitting units, and a connection layer for connecting two adjacent light emitting units, each light emitting unit comprising a light emitting layer; the connection layer comprises a lower sub-connection layer and an upper sub-connection layer stacked and connected with each other, and at least one of the sub-connection layers is a gradually-doped connection layer in direct contact with its adjacent light emitting layer.

### BACKGROUND OF THE INVENTION

Field of the Invention

Embodiments of the present disclosure generally relate to the field of light emitting devices, and particularly, to a laminated organic electroluminescent device and a method of manufacturing the same, and a display device comprising the laminated organic. electroluminescent device.

Description of the Related Art

Organic electroluminescent devices (e.g., OLED) have characteristics such as low energy consumption, low driving voltage, wide color gamut, simple manufacturing processes, wide angle of view, fast response and the like, and become research hotspots in the world recently.

In order to achieve functions of the organic electroluminescent devices in a better way, a laminated organic electroluminescent device is developed by a researcher by stacking a plurality of light emitting unit in an organic electroluminescent device and connecting the light emitting units through connection layers. This laminated organic electroluminescent device has a lower current density, and thereby can effectively avoid a thermal quenching effect due to excess current, and increase current efficiency, brightness, life and the like of the organic electroluminescent device.

However, since the number of functional layers included in the laminated organic electroluminescent device is larger, carriers need to get over a relatively larger interface barrier during entering the light emitting layer, and thus are prone to be accumulated on respective interfaces. In order to enable the carriers to get over the interface barrier and normally enter the light emitting layer so as to form excitons for lighting, it is necessary to increase the driving voltage for the carriers, which will lead to reduce in luminescence efficiency of the laminated organic electroluminescent device. Thus, it is an important issue for those skilled in the art that a laminated organic electroluminescent device is provided to enable effective improvement of luminescence efficiency.

### SUMMARY

Embodiments of the present disclosure provide a laminated organic electroluminescent device and a method of manufacturing the same, and a display device comprising the laminated organic electroluminescent device, for reducing number of layers of and improving luminescence efficiency of the laminated organic electroluminescent device.

In one aspect of the present disclosure, there is provided a laminated organic electroluminescent device, comprising at least two stacked light emitting units and a connection layer for connecting two adjacent light emitting units, each light emitting unit comprising a light emitting layer, the connection layer comprises a lower sub-connection layer and an upper sub-connection layer stacked and connected with each other, wherein at least one of the sub-connection layers is a gradually-doped connection layer in direct contact with an adjacent light emitting layer.

In the above laminated organic electroluminescent device, the gradually-doped connection layer may be consisted of a main body and a dopant, wherein a mass percentage of the dopant is zero at one side of the gradually-doped connection layer in contact with the light emitting layer, gradually increased toward the other side of the gradually-doped connection layer not in contact with the light emitting layer, and reaches a maximum value at the other side not in contact with the light emitting layer.

In the above laminated organic electroluminescent device, an upper limit of the maximum value may be 30 wt % when the dopant is a metal; the upper limit of the maximum value may be 50 wt % when the dopant is a metal compound; and the upper limit of the maximum value may be 80 wt % when the dopant is an organic substance.

In the above laminated organic electroluminescent device, the metal may comprise at least one selected from lithium, kalium, rubidium, cesium, magnesium, calcium and sodium; the metal compound may comprises at least one selected from MoO₃, V₂O₅, WO₃, Cs₂CO₃, LiF, Li₂CO₃, NaCl, FeCl₃ and Fe₃O₄; and the organic matter may comprise at least one selected from C₆₀, pentacene, F4-TCNQ and phthalocyanine derivatives.

In the above laminated organic electroluminescent device, when the upper sub-connection layer is an N type gradually-doped layer, the lower sub-connection layer may be any one of a P type gradually-doped layer, a P type uniformly-doped layer and a P type undoped layer; and when the upper sub-connection layer is a P type gradually-doped layer, the lower sub-connection layer may be any one of an N type uniformly-doped layer, an N type undoped layer and an N type gradually-doped layer.

In the above laminated organic electroluminescent device, only one of the lower sub-connection layer and the upper sub-connection layer may be a gradually-doped connection layer, and a light emitting unit adjacent to the other sub-connection layer may comprise a carrier transportation layer in contact with the other sub-connection layer.

In the above laminated organic electroluminescent device, a thickness of the gradually-doped connection layer may be in a range of 20 nm˜420 nm.

In another aspect of the present disclosure, there is provided method of manufacturing a laminated organic electroluminescent device, comprising steps of:

forming a first light emitting unit comprising a first light emitting layer;

forming a lower sub-connection layer and an upper sub-connection layer on the first light emitting unit successively; and

forming a second light emitting unit comprising a second light emitting layer on the upper sub-connection layer,

wherein at least one of the lower sub-connection layer and the upper sub-connection layer is formed as a gradually-doped connection layer in direct contact with an adjacent light emitting layer.

In the above method, the gradually-doped connection layer may be consisted of a main body and a dopant, wherein a mass percentage of the dopant is zero at one side of the gradually-doped connection layer in contact with the light emitting layer, gradually increase toward the other side of the gradually-doped connection layer not in contact with the light emitting layer, and reach a maximum value at the other side not in contact with the light emitting layer.

In the above method, if the lower sub-connection layer is a gradually-doped connection layer, when forming the gradually-doped connection layer, an evaporation rate for the main body is kept constant and an evaporation rate for the dopant is uniformly increased, or an evaporation rate of a dopant material is kept at a set value and an evaporation rate of a main body material is uniformly decreased, or the evaporation rate of the main body material is uniformly decreased while the evaporation rate of the dopant material is increased, such that the mass percentage of the dopant uniformly increases as a thickness of the lower sub-connection layer increases until the mass percentage reaches the maximum value.

In the above method, if the upper sub-connection layer is a gradually-doped connection layer, when forming the gradually-doped connection layer, an evaporation rate for the main body is kept constant and an evaporation rate for the dopant is uniformly decreased, or an evaporation rate of a dopant material is kept at a set value and an evaporation rate of a main body material is uniformly increased, or the evaporation rate of the main body material is uniformly increased while the evaporation rate of the dopant material is uniformly decreased, such that the mass percentage of the dopant uniformly decreases from the maximum value as a thickness of the upper sub-connection layer increases until the mass percentage decreases to zero.

In the above method, an upper limit of the maximum value may be 30 wt % when the dopant is a metal; the upper limit of the maximum value may be 50 wt % when the dopant is a metal compound; and the upper limit of the maximum value may be 80 wt % when the dopant is an organic substance.

In the above method, the lower sub-connection layer and the upper sub-connection layer may be deposited in order on the first light emitting unit by any one process selected from vacuum evaporating, spin coating, organic steam jet printing, organic vapor phase deposition, screen printing and ink jet printing.

In the above method, the evaporation rate of the dopant is in a range of 0˜0.4 nm/s.

In the above method, a thickness of the gradually-doped connection layer may be in range of 20 nm˜120 nm.

In a further aspect of the present disclosure, there is provided a display device, comprising the above laminated organic electroluminescent device or the laminated organic electroluminescent device obtained according to the above method.

Embodiments of the present disclosure provide a laminated organic electroluminescent device and a method of manufacturing the same, and a display device comprising the laminated organic electroluminescent device. In the laminated organic electroluminescent device, at least one of the sub-connection layers of the connection layer is provided as a gradually-doped connection layer, which, in place of an injection layer and a transportation layer, aids in injection and transportation of carriers. Thus, in the laminated organic electroluminescent device provided according to the present disclosure, no injection layer and transportation layer need to be provided between the light emitting layer and the gradually-doped connection layer, thereby reducing the number of functional layers included in the laminated organic electroluminescent device, decreasing the driving voltage required by the laminated organic electroluminescent device, and improving the luminescence efficiency of the laminated organic electroluminescent device.

### BRIEF DESCRIPTION OF THE DRAWINGS

Features and advantages of the present disclosure will be understood more clearly with reference to the accompanying drawings, which are illustrative and should not be interpreted being limitative to the present disclosure. Elements in the drawings are not necessarily drawn to scale, but are emphasized to illustrate principles of the present disclosure. The same reference numerals refer to the same or corresponding parts in respective drawings. In the drawings:

FIG. 1 is a schematically structural diagram of a laminated organic electroluminescent device according to example 1 of the present disclosure;

FIG. 2 is a schematically structural diagram of a laminated organic electroluminescent device according to example 2 of the present disclosure;

FIG. 3 is a schematically structural diagram of a laminated organic electroluminescent device according to example 3 of the present disclosure; and

FIG. 4 is a schematically structural diagram of a laminated organic electroluminescent device according to a comparison example.

### DETAILED DESCRIPTION OF PREFERRED EMBODIMENTS

Technique solution in embodiments of the present disclosure will be described clearly and thoroughly hereinafter. Obviously, the described embodiments are only some, rather than all, of embodiments of the present disclosure. Based on the embodiments of the present disclosure, all of other embodiments obtained by those skilled in the art without any creative work will fall within the scope of the present invention.

Embodiments of the present disclosure provides a laminated organic electroluminescent device, comprising at least two stacked light emitting units, and a connection layer for connecting two adjacent light emitting units, each light emitting unit comprising a light emitting layer; the connection layer comprises a lower sub-connection layer and an upper sub-connection layer stacked and connected with each other, at least one of the sub-connection layers is a gradually-doped connection layer in direct contact with an adjacent light emitting layer.

Currently, each light emitting unit of a laminated organic electroluminescent device includes a transportation layer and an injection layer; further, in order to avoid reduction in luminescence efficiency due to exciton annihilation, a charge buffer layer is generally inserted between the transportation layer and the light emitting unit, so that the number of functional layers included in the device greatly increases. Increasing in the number of functional layers will increase interface barrier among respective layers of the device, thereby resulting in increasing in a working voltage of the device, and adversely affecting the luminescence efficiency of the laminated organic electroluminescent device. Thus, in order to reduce the number of functional layers included in the laminated organic electroluminescent device, decrease the driving voltage required by the laminated organic electroluminescent device, and improving the luminescence efficiency of the laminated organic electroluminescent device, at least one of sub-connection layers of the connection layer is provide as a gradually-doped connection layer in embodiments of the present disclosure. The gradually-doped connection layer provided in the embodiments of the present disclosure may comprises a main body material which is the same as that of a transportation layer in prior arts, enabling a better transportation of carriers; moreover, mass percentages of components of the gradually-doped connection layer uniformly vary as the thickness of the gradually-doped connection layer increases, have no sudden change, thereby effectively reducing interface barriers among the respective layers.

Embodiments of the present disclosure provides a laminated organic electroluminescent device, in which at least one of sub-connection layers of the connection layer is provide as a gradually-doped connection layer, since the gradually-doped connection layer can, in place of an injection layer and a transportation layer, aid in injection and transportation of carriers, no injection layer and transportation layer need to be provided between the light emitting layer and the gradually-doped connection layer in the laminated organic electroluminescent device of the present disclosure, so that the number of functional layers included in the laminated organic electroluminescent device can be reduced, the driving voltage required by the laminated organic electroluminescent device is decreased, and the luminescence efficiency of the laminated organic electroluminescent device is improved.

In one embodiment of the present disclosure, the gradually-doped connection layer is consisted of a main body and a dopant, wherein a mass percentage of the dopant is zero at one side of the gradually-doped connection layer in contact with the light emitting layer, gradually increased toward the other side of the gradually-doped connection layer not in contact with the light emitting layer, and reaches a maximum value at the other side not in contact with the light emitting layer.

In order to achieve a better transportation of carriers, the mass percentage of the dopant is set to zero at one side of the gradually-doped connection layer in contact with the light emitting layer, and reaches a maximum value at the other side of gradually-doped connection layer not in contact with the light emitting layer (that is, at an interface between upper sub-connection layer and the lower sub-connection layer of the connection layer), which is intended to set the mass percentage of the dopant in the gradually-doped connection layer to be relatively lower at the side of the gradually-doped connection layer adjacent to the light emitting layer so as to enable a better transportation of carriers, and to be relatively higher at the side the gradually-doped connection layer away from the light emitting layer so as to enable a better injection of carriers. Thus, the gradually-doped connection layer provided in this embodiment can replace the injection layer and the transportation layer better, so as to reduce the number of functional layers included in the laminated organic electroluminescent device, decrease the driving voltage required by the laminated organic electroluminescent device and improve the luminescence efficiency of the laminated organic electroluminescent device.

In another embodiment of the present disclosure, an upper limit of the maximum value is about 30 wt % when the dopant is a metal; the upper limit of the maximum value is about 50 wt % when the dopant is a metal compound; and the upper limit of the maximum value is about 80 wt % when the dopant is an organic substance.

The dopant in the connection layer provided in the present embodiment mainly functions to provide carrier. Since the dopant (e.g., some metals) will diffuse into the organic main body as time elapses, which will result in reduction in life of the device, the mass percentage of the dopant in the gradually-doped connection layer needs to be kept in a reasonable range so as to avoid undesirable phenomena due to over low or high mass percentage of the dopant.

Since a metal comprises a number of free electrons therein, and has a good electron transportation property (that is, high electron mobility), higher electron affinity energy and higher ionization energy, it tends to inject electrons into the light emitting layer and can block injection of holes better, and is generally used as a dopant for an N type doped layer; while an organic matter has a good hole transportation property (that is, high hole mobility) and a lower electron affinity energy, tends to inject holes into the light emitting layer and can block injection of electrons better, it is generally used as a dopant for a P type doped layer; carrier injection properties of a metal oxide is between those of the metal and the organic matter, suitable dopants may be selected by those skilled in the art according to actual conditions.

Here, it is noted that since the metal dopant has a higher conductivity, a stronger ability to provide carriers and relatively reactive chemical properties, its mass percentage has a relative lower upper limit of about 30 wt %; in contrast, the organic matter dopant has a lower conductivity and a relatively weaker ability to provide carriers, thus its mass percentage has a relative higher upper limit of about 80 wt %; properties of the metal oxide dopant is between the metal dopant and the organic matter dopant, thus, the mass percentage of the metal oxide dopant generally has an upper limit of about 50 wt %. A suitable range of mass percentage may be selected according to the selected dopant, so that effectively, the gradually-doped connection layer can provide sufficient carriers to the light emitting layer, has a suitable conductivity, and can avoid deterioration of the connection layer.

In a further embodiment of the present disclosure, the metal includes at least one selected from lithium, kalium, rubidium, cesium, magnesium, calcium and sodium; the metal compound includes at least one selected from MoO₃, V₂O₅, WO₃, Cs₂CO₃, LiF, Li₂CO₃, NaCl, FeCl₃ and Fe₃O₄; and the organic matter includes at least one selected from C₆₀, pentacene, F4-TCNQ (2,3,5,6-Tetrafluoro-7′,7,8,8′-tetracyanoquinodimethane) and phthalocyanine derivatives.

As mentioned above, the gradually-doped connection layer can substantially achieve transportation of carriers. In order to enable more favorable injection of the carriers into the light emitting layer, the dopant also needs to be appropriately selected. The dopant provided in embodiments of the present disclosure has good film forming property and thermal stability, and will be not prone to crystallize, thus homogeneous and compact film layers can be formed finally. It will be understood that the dopant used the gradually-doped connection layer is not limited to above materials, which are only used as preferred examples of the dopant, and a wider range of suitable materials may be selected for the dopant by those skilled in the art according to characteristics of the dopant.

In a further embodiment of the present disclosure, when the upper sub-connection layer is an N type gradually-doped layer, the lower sub-connection layer may be any one of a P type gradually-doped layer, a P type uniformly-doped layer and a P type undoped layer; and when the upper sub-connection layer is a P type gradually-doped layer, the lower sub-connection layer may be any one of an N type uniformly-doped layer, an N type undoped layer and an N type gradually-doped layer.

The most suitable solution may be selected from the above six arrangements by those skilled in the art according to actual conditions. A preferred arrangement is a combination of an N type gradually-doped layer and a P type gradually-doped layer. As mentioned above, since the gradually-doped connection layer can, in place of an injection layer and a transportation layer, achieve injection and transportation of carriers (the N type gradually-doped layer achieves injection and transportation of electron carriers; the P type gradually-doped layer achieves injection and transportation of hole carriers), both the upper and lower sub-connection layers of the connection layer are provided as gradually-doped connection layers in order to greatly reduce the number of functional layers included in the laminated organic electroluminescent device, thereby improving luminescence efficiency to the largest extent.

It is noted that a transportation layer may be also provided between the connection layer and the light emitting unit. Luminous power of the laminated organic electroluminescent device will be improved by providing the transportation layer because the transportation layer can provide a better transportation of carriers. On the other hand, although the luminous power of the device may be improved to some extent by providing the transportation layer, it is unnegligible that the transportation layer will have some undesirable affect to the luminescence efficiency. Thus, those skilled in the art may determine, according to actual conditions, whether or not an electron transportation layer and/or a hole transportation layer needs to he appropriately provided on either side of the connection layer.

It will be understood that the connection layer provided in embodiments of the present disclosure is used to connect adjacent light emitting units in the laminated organic electroluminescent device, and a single laminated organic electroluminescent device may comprise a plurality of the above described connection layers corresponding to number of the light emitting units, in order to greatly reduce the number of layers included in the laminated organic electroluminescent device and to improve luminescence efficiency. It is noted that colors of light emitted by the light emitting units of the present disclosure may be red, green or blue, and the light emitting layers of respective light emitting units may be a doped layer or undoped layer, thus suitable light emitting units may be selected according to actual conditions by those skilled in the art to manufacture the laminated organic electroluminescent device.

Embodiments of the present disclosure further provide a method of manufacturing the laminated organic electroluminescent device provided according to the above embodiments, comprising: forming a first light emitting unit comprising a first light emitting layer; forming a lower sub-connection layer and an upper sub-connection layer on the first light emitting unit in order; and forming a second light emitting unit comprising a second light emitting layer on the upper sub-connection layer, wherein at least one of the lower sub-connection layer and the upper sub-connection layer is formed as a gradually-doped connection layer in direct contact with its adjacent light emitting layer.

According to exemplary embodiments of the present disclosure, during manufacturing the gradually-doped connection layer, evaporation rates of the main body and the dopant of the gradually-doped connection layer may be controlled to adjust mass percentages of the main body and the dopant in the gradually-doped connection layer, so that the gradually-doped connection layer may be manufactured without use of new apparatuses, thereby reducing production cost and difficulty of the laminated organic electroluminescent device provided in the present disclosure.

In one example, when the lower sub-connection layer is a gradually-doped connection layer, the mass percentage of the dopant is caused to be uniformly increased as a thickness of the lower sub-connection layer is increased until reaching the maximum value by keeping an evaporation rate for the main body constant and by uniformly or gradually increasing an evaporation rate for the dopant; when the upper sub-connection layer is a gradually-doped connection layer, the mass percentage of the dopant is caused to be uniformly decreased from the maximum value as a thickness of the upper sub-connection layer is increased until being decreased to zero by keeping the evaporation rate for the main body constant and by uniformly or gradually decreasing the evaporation rate for the dopant.

In embodiments of the present disclosure, a main body material and a dopant material are simultaneously evaporated and deposited for purpose of achieve doping in a film layer. Since mass percentages of the main body material and the dopant material in the gradually-doped connection layer depend on vapor deposition rates of the main body material and the dopant material, which, in turn, depend on evaporation rates of the main body material and the dopant material, the mass percentage of the dopant uniformly varies as the thickness is increased by uniformly or gradually changing the evaporation rate of the dopant material in embodiments of the present disclosure, thereby manufacturing the gradually-doped connection layer.

Specifically, when the lower sub-connection layer is a gradually-doped connection layer, a lower bottom surface of the lower sub-connection layer is in contact with the light emitting layer, thus the mass percentage of the dopant is zero at the lower bottom surface, and reach the maximum value at an upper surface (that is, at an interface between the upper and lower sub-connection layers in the connection layer). During manufacturing, the main body material and the dopant material are preheated, so that when the evaporation rate of the main body material reaches a set value and is kept constant, the dopant material is heated to evaporate, and the evaporation rate of the dopant material is uniformly increased from zero so that the dopant material is deposited while the main body material is being deposited, until the evaporation rate of the dopant material reaches a preset maximum value.

It will be understood that, during manufacturing the lower sub-connection layer which is a gradually-doped connection layer, the evaporation rate of the dopant material may be kept at a set value, and the evaporation rate of the main body material is uniformly decreased; or, the evaporation rate of the main body material is uniformly decreased while increasing the evaporation rate of the dopant material, so that the mass percentage of the dopant is uniformly increased as the thickness of the lower sub-connection layer is increased. A more suitable rate control mode may be selected by those skilled in the art according to actual apparatuses and process conditions, and it is noted that the evaporation rates of respective materials depend on temperatures of the materials, thus the evaporation rates of the respective materials may be controlled by those skilled in the art by controlling temperatures of the materials.

In contrast to the lower sub-connection layer, when the upper sub-connection layer is a gradually-doped connection layer, the mass percentage of the dopant in the upper sub-connection layer is maximum value at the lower bottom surface of the upper sub-connection layer (that is, at the interface between the two sub-connection layers), and is uniformly decreased from the lower bottom surface to zero at the upper surface. Thus, during manufacturing the upper sub-connection layer which is the gradually-doped connection layer, the main body material and the dopant material may be preheated, and begin to be deposited simultaneously after reaching respective preset evaporation rates, and the evaporation rate of the dopant material is uniformly decreased from the set maximum value during being deposited until being decreased to zero, so that the mass percentage of the dopant in the upper sub-connection layer uniformly decreases as the thickness of the upper sub-connection layer increases.

It will be understood that, during manufacturing the upper sub-connection layer which is the gradually-doped connection layer, the evaporation rate of the dopant material may be kept constant, and the evaporation rate of the main body material is uniformly increased; or, the evaporation rate of the main body material is uniformly increased while uniformly decreasing the evaporation rate of the dopant material, so that the mass percentage of the dopant is uniformly decreased as the thickness of the upper sub-connection layer is increased. The same principle has been described when manufacturing the above lower sub-connection layer, and thus will not be repeatedly described again here.

In a still further embodiment of the present disclosure, an upper limit of the maximum value is about 30 wt % when the dopant is a metal; the upper limit of the maximum value is about 50 wt % when the dopant is a metal compound; and the upper limit of the maximum value is about 80 wt % when the dopant is an organic substance. Influence of various dopants on functions of the gradually-doped connection layer and arrangement principle of mass percentages of various dopants have been mentioned above, and will not be repeatedly described again here. It is noted that during the gradually-doped connection layer, mass percentages of respective materials depend on respective evaporation rates, which, in turn, correspond to temperatures of the materials, thus temperature values of the materials need to be set according to factors such as characteristics of the materials, apparatuses, environment or the like, so that the range of mass percentage of the dopant in the gradually-doped connection layer meets requirements of the device.

In a further embodiment of the present disclosure, the lower sub-connection layer and the upper sub-connection layer are deposited in order on the light emitting unit by any one selected from vacuum evaporating, spin coating, organic steam jet printing, organic vapor phase deposition, screen printing and ink jet printing. Currently, films of the light emitting device may be manufactures in various ways which have different advantages and defects. For example, a spin coating process is simple and easily operated, but has a low coefficient of utilization of materials; a film layer manufactured by an organic vapor phase deposition process has a higher purity, but also has a relatively higher cost, in embodiments of the present disclosure, the gradually-doped connection layer is preferably manufactured through a vacuum evaporating process, in which a material to be formed into a film is placed and evaporates or sublimes in a vacuum environment so as to be precipitated on a surface of a workpiece or substrate, and which is advantageous in uniform and compact film formation quality and faster film formation speed, can achieve manufacturing of the gradually-doped connection layer in the present disclosure without modifying existing evaporation apparatuses, and thus can reduce production cost of the connection layer greatly. It will be understood that, the way of depositing the lower sub-connection layer and the upper sub-connection layer in order on the light emitting unit is not limited to that described above, and other ways may be selected by those skilled in the art according to actual conditions.

In a further embodiment of the present disclosure, the evaporation rate of the dopant is in a range of 0˜0.4 nm/s. Since the evaporation rate of the dopant has larger influence on formation of the gradually-doped connection layer, an over slow evaporation rate will lead to lower formation of the gradually-doped connection layer, while an over fast evaporation rate will result in that mass percentages of respective components of the gradually-doped connection layer are not easily controlled. Thus, in embodiments of the present disclosure, the evaporation rate of the dopant is in a range of 0˜0.4 nm/s, and preferably is 0.3 nm/s, at which a gradually-doped connection layer of high performance can be efficiently manufactured in an allowable range of the evaporation apparatus.

In a further embodiment of the present disclosure, the thickness of the gradually-doped connection layer is in a range of 20 nm˜120 nm. Since the gradually-doped connection layer has different effects from a conventional connection layer, and will implement functions of both of the transportation layer and the injection layer in prior arts, it is necessary that the gradually-doped connection layer has a certain thickness so that there is enough space for adjusting the mass percentage of the dopant, thereby enabling function of the injection layer in a better way; further, a portion of the connection layer in which the dopant has a lower weight percentage has a suitable thickness so as to enable function of the transportation layer in a better way. Therefore, in embodiments of the present disclosure, the thickness of the gradually-doped connection layer is set in the range of 20 nm˜120 nm, and preferably is 30 nm˜60 nm, more preferably 30 nm˜35 nm. With the preferable range of thickness, not only the gradually-doped connection layer can support lighting of the light emitting unit better, but also the luminescence efficiency of the device will not be reduced due to a over large thickness.

Embodiments of the present disclosure further provide a display device, comprising the above laminated organic electroluminescent device or the laminated organic electroluminescent device obtained according to the above method.

In order to better illustrate the laminated organic electroluminescent device and the method of manufacturing the same provided according to exemplary embodiments of the present disclosure, specific examples will be described in detail hereinafter.

### Example 1

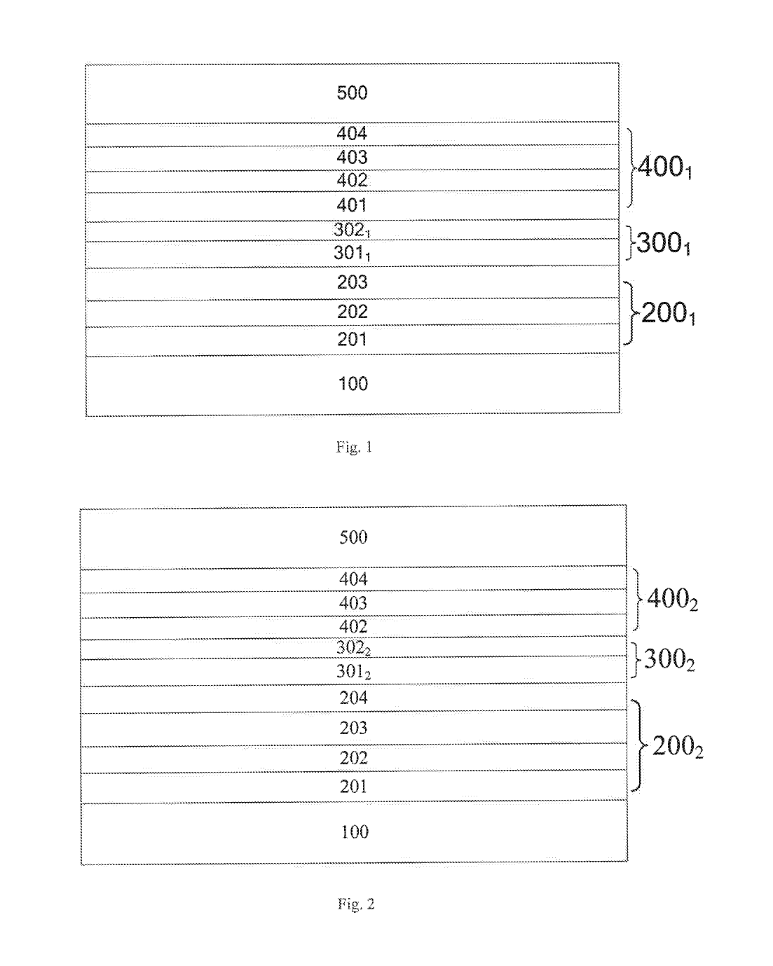

As shown in FIG. 1, a laminated organic electroluminescent device according to example 1 comprises a first light emitting unit 200₁, a connection layer 300₁, a second light emitting unit 400₁ and a cathode 500, which are stacked in order on a transparent glass substrate 100 with an ITO film. The first light emitting unit 200₁ comprises a hole injection layer 201, a hole transportation layer 202 and a light emitting layer 203 stacked on the substrate 100; the connection layer 300₁ comprises a lower sub-connection layer 301₁ and an upper sub-connection layer 302₂ stacked in order on first light emitting unit 200₁, wherein the lower sub-connection layer 301₁ is a gradually-doped connection layer in direct contact with the light emitting layer 203; the second light emitting unit 400₁ comprises a hole transportation layer 401, a light emitting layer 402, an electron transportation layer 403 and an electron buffer layer 404 stacked in order on the connection layer 300₁. In this example, the connection layer of the laminated organic electroluminescent device has an arrangement of N type gradually-doped layer/P type undoped layer, and arrangement of respective functional layers of the laminated organic electroluminescent device is shown in table 1.

TABLE 1
Laminated arrangement in example 1

| layer | | | | |
|---|---|---|---|---|
| sequence | | | | |
| (down→up) | functional layer | | material | thickness |
| 1 | ITO anode glass substrate | | ITO | 100 nm |
| 2 | first light | hole injection layer | MoO₃ | 5 nm |
| 3 | emitting unit | hole transportation layer | NPB | 40 nm |
| 4 | | light emitting layer | MAND:DSA-Ph | 30 nm |
| 5 | connection | N type gradually-doped | Bphen:Li (0~10 wt | 30 nm |
| | layer | layer | %) | |
| 6 | | P type undoped layer | MoO₃ | 5 nm |
| 7 | second light | hole transportation layer | NPB | 40 nm |
| 8 | emitting unit | light emitting layer | MAND:DSA-Ph | 30 nm |
| 9 | | electron transportation layer | Bphen | 30 nm |
| 10 | | electron buffer layer | LiF | 1 nm |

| | | | |
|---|---|---|---|
| 11 | cathode | Al | 120 nm |

In this example, the ITO glass substrate is a transparent glass with an indium oxide film thereon, a main body material of the light emitting layer is MAND, a dopant material of the light emitting layer is DSA-Ph; a main body material of the N type gradually-doped connection layer is Bphen, and a dopant material of the N type gradually-doped connection layer is metal Li. Specific manufacturing processes are provided as follows:

An ITO patterned electrode is formed on the transparent glass substrate with the ITO (having a surface resistance <30Ω/□) by lithography and etching processes; then the ITO glass substrate is ultrasonically cleaned sequentially in deionized water, acetone, and absolute ethyl alcohol; after finishing the ultrasonic cleaning, the substrate is dried by N₂ and is processed by O₂ plasma; the processed substrate is placed within a vapor deposition chamber, and after a gas pressure within the vapor deposition chamber is adjusted to be below 5×10⁻⁴ Pa, functional layers in table 1 are evaporated in order on a surface of the ITO is through a vacuum thermal evaporation process, wherein the dopant in the light emitting layer has a mass percentage of 3 wt % in the light emitting layer; in the N type gradually-doped connection layer, the mass percentage of the dopant is zero at a lower bottom surface, and is 10 wt % at an upper surface (that is, NP interface in the connection layer). It is noted that in the above evaporation process, in addition to use of a metal cathode mask (metal mask) for Al and an evaporation rate of 0.3 nm/s, evaporation rates of the main body material and the dopant material of the gradually-doped layer are set according to actual conditions, an open masks and an evaporation rate of 0.1 nm/s are applied for other layers.

The laminated organic electroluminescent device is a blue light device, which has a luminescence area of 3 mm×3 mm, a luminescence peak of 470 nm, a shoulder peak of 496 nm, a working voltage of 18V, and a current luminescence efficiency of 25.9 cd/A.

### Example 2

As shown in FIG. 2, a laminated organic electroluminescent device according to example 2 comprises a first light emitting unit 200₂, a connection layer 300₂, a second light emitting unit 400₂ and a cathode 500, which are stacked in order on a transparent glass substrate 100 with an ITO film. The first light emitting unit 200₂ comprises a hole injection layer 201, a hole transportation layer 202, a light emitting layer 203 and an electron transportation layer 204 stacked in order on the substrate 100, the connection layer 300₂ comprises a lower sub-connection layer 301₂ and an upper sub-connection layer 302₂ stacked in order on first light emitting unit 200₂, and the second light emitting unit 400₂ comprises a light emitting layer 402, an electron transportation layer 403 and an electron buffer layer 404 stacked in order on the connection layer 300₂, wherein the upper sub-connection layer 302₂ is a gradually-doped connection layer in direct contact with the light emitting layer 402. In this example, the connection layer of the laminated organic electroluminescent device has an arrangement of N type uniformly-doped layer/P type gradually-doped layer, and arrangement of respective functional layers of the laminated organic electroluminescent device is shown in table 2. Processes of manufacturing the device are implemented with reference to example 1.

TABLE 2
Laminated arrangement in example 2

| layer | | | | |
|---|---|---|---|---|
| sequence | | | | |
| (down→up) | functional layer | | material | thickness |
| 1 | ITO anode glass substrate | | ITO | 100 nm |
| 2 | first light | hole injection layer | MoO₃ | 5 nm |
| 3 | emitting | hole transportation layer | NPB | 40 nm |
| 4 | unit | light emitting layer | MAND:DSA-Ph | 30 nm |
| 5 | | electron transportation layer | Bphen | 15 nm |
| 6 | connection | N type uniformly-doped layer | Bphen:Li (10 wt %) | 10 nm |
| 7 | layer | P type gradually-doped layer | NPB:MoO₃ (30 wt | 30 nm |
| | | | %-~0) | |
| 8 | second light | light emitting layer | MAND:DSA-Ph | 30 nm |
| 9 | emitting | electron transportation layer | Bphen | 30 nm |
| 10 | unit | electron buffer layer | LiF | 1 nm |

| | | | |
|---|---|---|---|
| 11 | cathode | Al | 120 nm |

The laminated organic electroluminescent device is a blue light device, which has a luminescence area of 3 mm×3 mm, a luminescence peak of 470 nm, and a shoulder peak of 496 nm.

### Example 3

As shown in FIG. 3, a laminated organic electroluminescent device according to example 3 comprises a first light emitting unit 200₃, a connection layer 300₃, a second light emitting unit 400₃ and a cathode 500, which are stacked in order on a transparent glass substrate 100 with an ITO film. The first light emitting unit 200₃ comprises a hole injection layer 201, a hole transportation layer 202 and a light emitting layer 203 stacked on the substrate 100, the connection layer 300₃ comprises a lower sub-connection layer 301₃ and an upper sub-connection layer 302₃ stacked in order on first light emitting unit 200₃, and the second light emitting unit 400₃ comprises a light emitting layer 402, an electron transportation layer 403 and an electron buffer layer 404 stacked in order on the connection layer 300₃, wherein the lower sub-connection layer 301₃ is a gradually-doped connection layer in direct contact with the light emitting layer 203, and the upper sub-connection layer 302₃ is a gradually-doped connection layer in direct contact with the light emitting layer 402. In this example, the connection layer of the laminated organic electroluminescent device has an arrangement of N type gradually-doped layer/P type gradually-doped layer, and arrangement of respective functional layers of the laminated organic electroluminescent device is shown in table 3. Processes of manufacturing the device are implemented with reference to example 1.

TABLE 3
Laminated arrangement in example 3

| layer | | | | |
|---|---|---|---|---|
| sequence | | | | |
| (down→up) | functional layer | | material | thickness |
| 1 | ITO anode glass substrate | | ITO | 100 nm |
| 2 | first light | hole injection layer | MoO₃ | 5 nm |
| 3 | emitting unit | hole transportation | NPB | 40 nm |
| | | layer | | |
| 4 | | light emitting layer | MAND:DSA-Ph | 30 nm |
| 5 | connection | N type | Bphen:Li (0~10 wt %) | 30 nm |
| | layer | gradually-doped layer | | |
| 6 | | P type | NPB:MoO₃(30 wt | 50 nm |
| | | gradually-doped layer | %~0) | |
| 7 | second light | light emitting layer | MAND:DSA-Ph | 30 nm |
| 8 | emitting unit | electron transportation | Bphen | 30 nm |
| | | layer | | |
| 9 | | electron buffer layer | LiF | 1 nm |

| | | | |
|---|---|---|---|
| 10 | cathode | Al | 120 nm |

The laminated organic electroluminescent device is a blue light device, which has a luminescence area of 3 mm×3 mm, a luminescence peak of 470 nm, and a shoulder peak of 496 nm.

### COMPARISON EXAMPLE

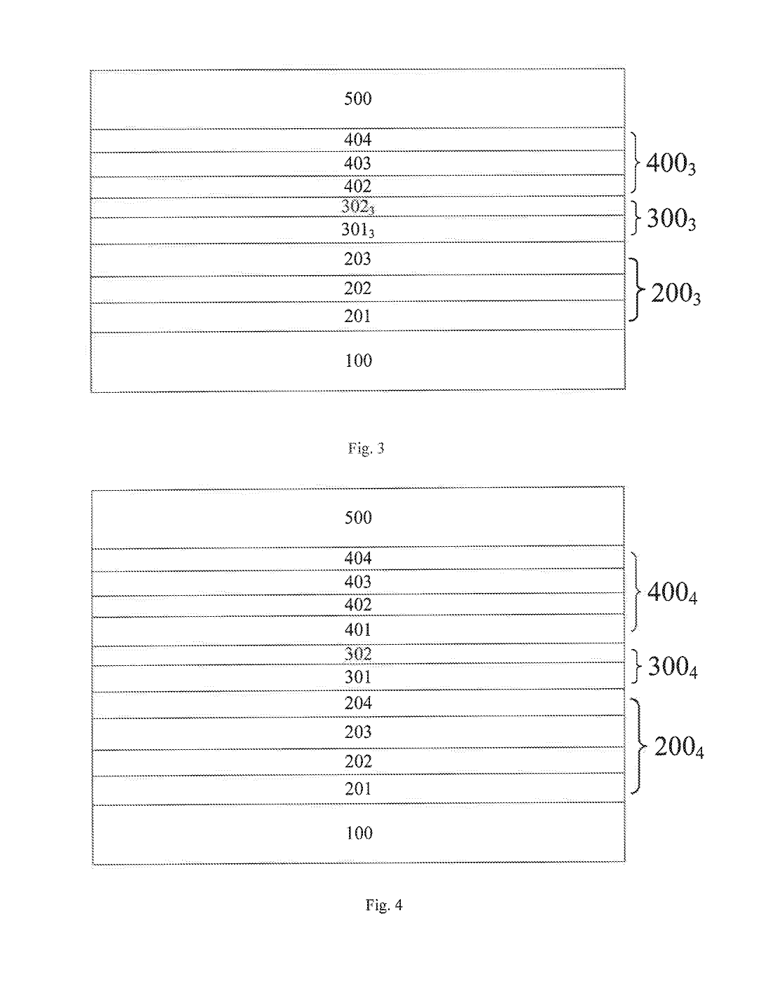

Compared to the above three examples, there is provided a laminated organic electroluminescent device manufactured in prior arts. As shown in FIG. 4, the laminated organic electroluminescent device according to comparison example comprises a first light emitting unit 200₄, a connection layer 300₄, a second light emitting unit 400₄ and a cathode 500, which are stacked in order on a transparent glass substrate 100 with an ITO film. The first light emitting unit 200₄ comprises a hole injection layer 201, a hole transportation layer 202, a light emitting layer 203 and an electron transportation layer 204 stacked in order on the substrate 100, the connection layer 300₄ comprises a lower sub-connection layer 301₄ and an upper sub-connection layer 302₄ stacked in order on first light emitting unit 200₄, and the second light emitting unit 400₄ comprises a hole transportation layer 401, a light emitting layer 402, an electron transportation layer 403 and an electron buffer layer 404 stacked in order on the connection layer 300₄, wherein the lower sub-connection layer 301₄ is a uniformly-doped connection layer, and the upper sub-connection layer 302₄ is a non-uniformly-doped connection layer. Arrangement of respective functional layers of the laminated organic electroluminescent device according to the comparison example is shown in table 4.

TABLE 4
Laminated arrangement in comparison example

| layer | | | | |
|---|---|---|---|---|
| sequence | | | | |
| (down→up) | functional layer | | material | thickness |
| 1 | ITO anode glass substrate | | ITO | 100 nm |
| 2 | first light | hole injection layer | MoO₃ | 5 nm |
| 3 | emitting | hole transportation layer | NPB | 40 nm |
| 4 | unit | light emitting layer | MAND:DSA-Ph | 30 nm |
| 5 | | electron transportation layer | Bphen | 15 nm |
| 6 | connection | N type uniformly-doped layer | Bphen:Li (10 wt | 10 nm |
| | layer | | %) | |
| 7 | | P type undoped layer | MoO₃ | 5 nm |
| 8 | second light | hole transportation layer | NPB | 40 nm |
| 9 | emitting | light emitting layer | MAND:DSA-Ph | 30 nm |
| 10 | unit | electron transportation layer | Bphen | 30 nm |
| 11 | | electron buffer layer | LiF | 1 nm |

| | | | |
|---|---|---|---|
| 12 | cathode | Al | 120 nm |

The laminated organic electroluminescent device is a blue light device, which has a luminescence area of 3 mm×3 mm, a luminescence peak of 470 nm, and a shoulder peak of 496 nm.

The above examples are compared with the comparison example, and the luminescence efficiency thereof are tested under a current density of 2 mA/cm², thereby obtaining results shown in table 5.

TABLE 5
Comparison results between examples of the
present disclosure example and comparison example

| | number of | | luminescence |
|---|---|---|---|
| | functional | working voltage | efficiency |
| device | layers | (V) | (cd/A) |
| example 1 | 11 | 18 | 24.5 |
| example 2 | 11 | 16 | 25.9 |
| example 3 | 10 | 11 | 27.3 |
| comparison example | 12 | 18 | 18.5 |

As can be seen from table 5, with the same current density, the laminated organic electroluminescent devices in the examples 1, 2, 3 of the present disclosure has the number of layers smaller than that of the comparison example, and their luminescence efficiencies are respectively 24.5 cd/A, 25.9 cd/A and 27.3 cd/A, while the luminescence efficiency in the comparison example is 18.3 cd/A. Accordingly, it can be determined that the luminescence efficiency does be improved in the laminated organic electroluminescent device provided according to the present disclosure. In terms of working voltage, the working voltage in examples 2 and 3 are respectively 16V and 11V, both of which are smaller than the working voltage in prior arts. Thus, the laminated organic electroluminescent device provided according to the present disclosure can effectively reduce working voltage.

It can be found, when comparing the examples 1, 2, 3, that the example 3 has a higher luminescence efficiency and a lower working voltage relative to the examples 1 and 2, this is mainly because the connection layer in the examples 1 and 2 only includes one gradually-doped connection layer respectively, while both the two sub-connection layers in the example 3 are gradually-doped sub-connection layers, which shows that the preferred arrangement of the connection layer of the present disclosure, in which both the two upper and lower sub-connection layers are gradually-doped connection layers, can enable higher luminescence efficiency of the laminated organic electroluminescent device.

It will be obvious that the above embodiments are given for purpose of clear description by ways of examples, instead of limiting the present invention. The skilled person in the art would appreciate that various changes or modifications may be made based on the above description. It is not necessary to describe all embodiments exhaustively. Obvious changes or modifications derived from the present document will fall within scopes of the present invention.

1. A laminated organic electroluminescent device, comprising at least two stacked light emitting units and a connection layer for connecting two adjacent light emitting units, each light emitting unit comprising a light emitting layer;
the connection layer comprises a lower sub-connection layer and an upper sub-connection layer stacked and connected with each other, wherein at least one of the sub-connection layers is a gradually-doped connection layer in direct contact with an adjacent light emitting layer.

2. The laminated organic electroluminescent device according to claim 1, wherein
the gradually-doped connection layer is consisted of a main body and a dopant, wherein a mass percentage of the dopant is zero at one side of the gradually-doped connection layer in contact with the light emitting layer, gradually increases toward the other side of the gradually-doped connection layer not in contact with the light emitting layer, and reaches a maximum value at the other side not in contact with the light emitting layer.

3. The laminated organic electroluminescent device according to claim 2, wherein
an upper limit of the maximum value is 30 wt % when the dopant is a metal;
the upper limit of the maximum value is 50 wt % when the dopant is a metal compound; and
the upper limit of the maximum value is 80 wt % when the dopant is an organic substance.

4. The laminated organic electroluminescent device according to claim 3, wherein
the metal includes at least one selected from lithium, kalium, rubidium, cesium, magnesium, calcium and sodium;
the metal compound includes at least one selected from MoO₃, V₂O₅, WO₃, Cs₂CO₃, LiF, Li₂CO₃, NaCl, FeCl₃ and Fe₃O₄; and
the organic substance includes at least one selected from C₆₀, pentacene, F4-TCNQ and phthalocyanine derivatives.

5. The laminated organic electroluminescent device according to claim 1, wherein
when the upper sub-connection layer is an N type gradually-doped layer, the lower sub-connection layer is any one of a P type gradually-doped layer, a P type uniformly-doped layer and a P type undoped layer; and
when the upper sub-connection layer is a P type gradually-doped layer, the lower sub-connection layer is any one of an N type uniformly-doped layer, an N type undoped layer and an N type gradually-doped layer.

6. The laminated organic electroluminescent device according to claim 1, wherein
only one of the lower sub-connection layer and the upper sub-connection layer is a gradually-doped connection layer, and a light emitting unit adjacent to the other sub-connection layer comprises a carrier transportation layer in contact with the other sub-connection layer.

7. The laminated organic electroluminescent device according to claim 1, wherein a thickness of the gradually-doped connection layer is in a range of 20 nm˜120 nm.

8. A method of manufacturing a laminated organic electroluminescent device, comprising steps of:
forming a first light emitting unit comprising a first light emitting layer;
forming a lower sub-connection layer and an upper sub-connection layer on the first light emitting unit successively; and
forming a second light emitting unit comprising a second light emitting layer on the upper sub-connection layer,
wherein at least one of the lower sub-connection layer and the upper sub-connection layer is formed as a gradually-doped connection layer in direct contact with an adjacent light emitting layer.

9. The method according to claim 8, wherein
the gradually-doped connection layer is consisted of a main body and a dopant, the dopant being distributed such that a mass percentage of the dopant is zero at one side of the gradually-doped connection layer in contact with the light emitting layer, gradually increases toward the other side of the gradually-doped connection layer not in contact with the light emitting layer, and reaches a maximum value at the other side not in contact with the light emitting layer.

10. The method according to claim 9, wherein if the lower sub-connection layer is a gradually-doped connection layer, when forming the gradually-doped connection layer, an evaporation rate for the main body is kept constant and an evaporation rate for the dopant is uniformly increased, or an evaporation rate of a dopant material is kept at a set value and an evaporation rate of a main body material is uniformly decreased, or the evaporation rate of the main body material is uniformly decreased while the evaporation rate of the dopant material is increased, such that the mass percentage of the dopant uniformly increases as a thickness of the lower sub-connection layer increases until the mass percentage reaches the maximum value.

11. The method according to claim 9, wherein if the upper sub-connection layer is a gradually-doped connection layer, when forming the gradually-doped connection layer, an evaporation rate for the main body is kept constant and an evaporation rate for the dopant is uniformly decreased, or an evaporation rate of a dopant material is kept at a set value and an evaporation rate of a main body material is uniformly increased, or the evaporation rate of the main body material is uniformly increased while the evaporation rate of the dopant material is uniformly decreased, such that the mass percentage of the dopant uniformly decreases from the maximum value as a thickness of the upper sub-connection layer increases until the mass percentage decreases to zero.

12. The method according to claim 8, wherein
an upper limit of the maximum value is 30 wt % when the dopant is a metal;
the upper limit of the maximum value is 50 wt % when the dopant is a metal compound; and
the upper limit of the maximum value is 80 wt % when the dopant is an organic substance.

13. The method according to claim 8, wherein
the lower sub-connection layer and the upper sub-connection layer are deposited successively on the first light emitting unit by any one process selected from vacuum evaporating, spin coating, organic steam jet printing, organic vapor phase deposition, screen printing and ink jet printing.

14. The method according to claim 10, wherein the evaporation rate of the dopant is in a range of 0˜0.4 nm/s.

15. The method according to claim 8, wherein the thickness of the gradually-doped connection layer is in a range of 20 nm˜120 nm.

16. A display device, comprising the laminated organic electroluminescent device according to claim 1.

17. The laminated organic electroluminescent device according to claim 2, wherein
when the upper sub-connection layer is an N type gradually-doped layer, the lower sub-connection layer is any one of a P type gradually-doped layer, a P type uniformly-doped layer and a P type undoped layer; and
when the upper sub-connection layer is a P type gradually-doped layer, the lower sub-connection layer is any one of an N type uniformly-doped layer, an N type undoped layer and an N type gradually-doped layer.

18. The laminated organic electroluminescent device according to claim 3, wherein
when the upper sub-connection layer is an N type gradually-doped layer, the lower sub-connection layer is any one of a P type gradually-doped layer, a P type uniformly-doped layer and a P type undoped layer; and
when the upper sub-connection layer is a P type gradually-doped layer, the lower sub-connection layer is any one of an N type uniformly-doped layer, an N type undoped layer and an N type gradually-doped layer.

19. The method according to claim 9, wherein
an upper limit of the maximum value is 30 wt % when the dopant is a metal;
the upper limit of the maximum value is 50 wt % when the dopant is a metal compound; and
the upper limit of the maximum value is 80 wt % when the dopant is an organic substance.

20. The method according to claim 10, wherein
an upper limit of the maximum value is 30 wt % when the dopant is a metal;
the upper limit of the maximum value is 50 wt % when the dopant is a metal compound; and
the upper limit of the maximum value is 80 wt % when the dopant is an organic substance.
